(19) United States
(12) Patent Application Publication
(10) Pub. No.: US 2011/0018089 A1
(43) Pub. Date: Jan. 27, 2011

(54) STACK STRUCTURE AND INTEGRATED STRUCTURE OF CIS BASED SOLAR CELL

(76) Inventors: Hideki Hakuma, Tokyo (JP); Yoshiaki Tanaka, Tokyo (JP); Tetsuya Aramoto, Tokyo (JP); Katsumi Kushiya, Tokyo (JP)

Correspondence Address: Tomoko Nakajima;Cermak Nakajima LLP, 127 S. Peyton Street, Suite 210, Alexandria, VA, 22314, US

(21) Appl. No.: 12/920,772

(22) PCT Filed: Mar. 7, 2008
(86) PCT No.: PCT/JP2008/054156

§ 371 Date: Sep. 2, 2010

(51) Int. Cl. H01L 31/0352

(52) U.S. Cl. 257/463; 257/461; 257/E31.032

(57) ABSTRACT

In a stack structure of a CIS based thin film solar cell obtained by stacking a p-type CIS light absorbing layer, a buffer layer, and an n-type transparent conductive film in that order, the buffer layer has a stack structure of two or more layers including first and second buffer layers, the first buffer layer adjoining the p-type light absorbing layer is made of a compound containing cadmium (Cd), zinc (Zn), or indium (In), the second buffer layer adjoining the first buffer layer is made of a zinc oxide-based thin film, the first buffer layer has a thickness equal to or smaller than 20 nm, and the second buffer layer has a thickness equal to or larger than 100 nm

### TECHNICAL FIELD

The present invention relates to a stack structure of a CIS based thin film solar cell and an integrated structure of a CIS based thin film solar cell.

### BACKGROUND ART

Currently, CIS based thin film solar cells are widely put into practical use. It is known that, when the CIS based thin film solar cells are manufactured, a thin film solar cell having a high conversion efficiency can be obtained by growing a cadmium sulfide (CdS) layer as a high-resistance buffer layer on an light absorbing layer made of a CuInSe₂-based thin film.

Patent Document 1 discloses a chemical bath deposition (CBD) method for chemically depositing a cadmium sulfide (CdS) thin film from a solution by immersing CuInSe₂ thin film light absorbing layer in a solution so that a thin film light absorbing layer and a high-quality heterojunction can be formed, and shunt resistance can increase.

In addition, Patent Document 2 discloses a method of manufacturing a thin film solar cell having a high conversion efficiency, as in the case where the cadmium sulfide (CdS) layer is used as a buffer layer, by using a zinc mixed-crystal compound, i.e., Zn(O,S,OH)ₓ composed of oxygen, sulfur, and a hydroxyl group chemically grown from a solution on a p-type light absorbing layer as the high-resistance buffer layer.

Furthermore, Patent Document 3 discloses a method of manufacturing a thin film by successively depositing a buffer layer and a window layer in that order on a glass substrate using a metal organic chemical vapor deposition (MOCVD) method.

Patent Document 1: U.S. Pat. No. 4,611,091

Patent Document 2: Japanese Patent No. 3249342

Patent Document 3: JP-A-2006-332440

### DISCLOSURE OF INVENTION

### Problems to be Solved by the Invention

In the technique disclosed in Patent Document 1 of the related art, when the cadmium sulfide (CdS) layer is grown as the high-resistance buffer layer, an effort is made to minimize the highly toxic cadmium (Cd) waste solution. However, since solid cadmium sulfide (CdS) and an alkali waste solution are abundantly produced, waste disposal costs increase, and accordingly, the manufacturing costs of the CIS solar cell increase.

Although Patent Document 2 discloses an effective manufacturing method for excluding the cadmium sulfide (CdS) buffer layer that is considered indispensible for manufacturing a thin film solar cell having a high conversion efficiency, the technique disclosed in Patent Citation 2 is to suppress leakage using the CBD buffer layer, and the technique disclosed in Patent Citation 3 is to suppress leakage using the buffer layer manufactured using the metal organic chemical vapor deposition (MOCVD) method. Therefore, it is desired to improve both techniques.

Particularly, the surface of the light absorbing layer manufactured by performing a sulfidization reaction at a high temperature for a long time contains a large number of leakage components such as a low-resistance Cu-Se compound and a Cu-S compound in order to obtain a high-quality light absorbing layer. Therefore, it has been demanded to reinforce leakage suppression in order to improve performance of the solar cells.

On the other hand, it is envisaged that leakage can be suppressed by thickening the CBD buffer layer functioning as the main component for suppressing leakage. However, as the CBD buffer layer is thickened, series resistance problematically increases, and as a result, leakage suppression disadvantageously becomes insufficient. Moreover, since the amount of waste produced accordingly increases, the manufacturing costs also increase.

The present invention has been made in order to solve the problem and drawbacks mentioned above and is aimed at providing a high-efficiency solar cell by which leakage can be suppressed, and p-n heterojunction interface characteristics can be improved without increasing the series resistance.

### PROBLEMS TO BE SOLVED BY THE INVENTION

In order to achieve the aforementioned object, according to a first aspect of the present invention, there is provided a stack structure of a CIS based thin film solar cell obtained by stacking a p-type CIS light absorbing layer, a buffer layer, and an n-type transparent conductive film in that order, wherein the buffer layer has a stack structure of two or more layers including first and second buffer layers, the first buffer layer adjoining the p-type CIS light absorbing layer is made of a compound containing cadmium (Cd), zinc (Zn), or indium (In), the second buffer layer adjoining the first buffer layer is made of a zinc oxide-based thin film, the first buffer layer has a thickness equal to or smaller than 20 nm, and the second buffer layer has a thickness equal to or larger than 100 nm.

According to another aspect of the present invention, there is provided a stack structure of a CIS based thin film solar cell obtained by stacking a p-type CIS light absorbing layer, a buffer layer, and an n-type transparent conductive film in that order, wherein the buffer layer has a stack structure of two or more layers including first and second buffer layers, the first buffer layer adjoining the p-type CIS light absorbing layer is made of a compound containing cadmium (Cd), zinc (Zn), or indium (In), the second buffer layer adjoining the first buffer layer is made of a zinc oxide-based thin film, and the ratio between a thickness of the first buffer layer and the thickness of the second buffer layer (the thickness of the second buffer layer/the thickness of the first buffer layer) is set to be equal to or larger than 5.

The first buffer layer may be formed using a chemical bath deposition (CBD) method.

The second buffer layer may be formed using a metal organic chemical vapor deposition (MOCVD) method.

The concentration of a dopant contained in the second buffer layer may be equal to or lower than 1×10¹⁹ atoms/cm³. In this case, the dopant may contain any one of aluminum (Al), gallium (Ga), or boron (B).

The first buffer layer may contain any one of CdₓS_{y}, ZnₓS_{y}, ZnₓO_{y}, Znₓ(OH)_{y}, InₓS_{y}, Inₓ(OH)_{y}, or InₓO_{y} (where, x and y denote any natural number).

A concentration of sulfur (S) on a surface of the p-type CIS light absorbing layer may be equal to or higher than 0.5 atoms %.

The second buffer layer may have resistivity equal to or higher than 0.1 Ωcm.

There may be provided an integrated structure of a CIS based thin film solar cell including the aforementioned stack structures.

### EFFECT OF THE INVENTION

According to the present invention, it is possible to suppress leakage without increasing the series resistance in the CIS based thin film solar cell, improve p-n heterojunction interface characteristics, and obtain a high-efficiency solar cell.

### BEST MODE FOR CARRYING OUT THE INVENTION

Hereinafter, a stack structure of the CIS based thin film solar cell according to an embodiment of the present invention will be described.

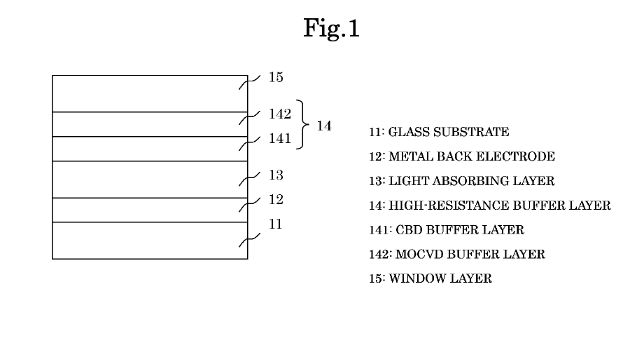

Referring to FIG. 1, the CIS based thin film solar cell according to the present embodiment includes a p-n heterojunction device having a substrate structure stacked in the order of a glass substrate 11, a metal back electrode layer 12, a p-type CIS light absorbing layer (hereinafter, referred to simply as an light absorbing layer) 13, a high-resistance buffer layer 14, and an n-type transparent conductive film (hereinafter, referred to simply as a window layer) 15.

The glass substrate 11 is a substrate on which each of the layers are stacked and includes a glass substrate such as soda lime glass, a metal substrate such as a stainless steel substrate, or a resin substrate such as a polyimide film.

The metal back electrode layer 12 is made of metal having a high anti-corrosion property and a high melting point, such as molybdenum (Mo) or titanium (Ti), having a thickness of 0.2 to 2 μm and manufactured on the glass substrate 11 by a DC sputtering method using such metal as a target.

The light absorbing layer 13 is a thin film having an I-III-VI₂ group chalcopyrite structure, a p-type conductivity, and a thickness of 1 to 3 μm. For example, the light absorbing layer 13 includes a multi-source compound semiconductor thin film such as CuInSe₂, Cu(InGa)Se₂, Cu(InGa)(SSe)₂. In addition, the light absorbing layer 13 may include a selenide-based CIS light absorbing layer, a sulfide-based CIS light absorbing layer, and a sulfide/selenide-based CIS light absorbing layer. The selenide-based CIS light absorbing layer may include CuInSe₂, Cu(InGa)Se₂, or CuGaSe₂. The sulfide-based CIS light absorbing layer may include CuInS₂, Cu(InGa)S₂, or CuGaS₂. The sulfide/selenide-based CIS light absorbing layer may include CuIn(SSe)₂, Cu(InGa) (SSe)₂, or CuGa(SSe)₂, and examples having a surface layer include CuInSe₂ having CuIn(SSe)₂ as a surface layer, Cu(InGa)Se₂ having CuIn(SSe)₂ as a surface layer, Cu(InGa) (SSe)₂ having CuIn(SSe)₂ as a surface layer, CuGaSe₂ having CuIn(SSe)₂ as a surface layer, Cu(InGa)Se₂ having Cu(InGa)(SSe)₂ as a surface layer, CuGaSe₂ having Cu(InGa)(SSe)₂ as a surface layer, Cu(InGa)Se₂ having CuGa(SSe)₂ as a surface layer, and CuGaSe₂ having CuGa(SSe)₂ as a surface layer.

Two kinds of methods are representatively used to manufacture the light absorbing layer 13: a selenide/sulfide method and a multi-source co-evaporation method.

In the selenide/sulfide method, the light absorbing layer 13 can be manufactured by forming a stack structure including copper (Cu), indium (In), and gallium (Ga) or a mixed-crystal metal precursor film (including Cu/In, Cu/Ga, Cu-Ga alloy/In, Gu-Ga-In alloy, or the like) on the metal back electrode layer 12 using a sputtering method or an evaporation method or the like and then performing heat treatment under a selenium and/or sulfur atmosphere.

In the multi-source co-evaporation method, the light absorbing layer 13 can be manufactured by simultaneously depositing source materials including copper (Cu), indium (In), gallium (Ga), and selenium (Se) in an appropriate combination on the glass substrate 11 having a back electrode layer 12 heated at a temperate equal to or higher than approximately 500° C.

Since an opticalband gap can increase in the light incident side by setting the concentration of sulfur on the surface of the light absorbing layer 13 (generally, up to 100 nm from the surface) to be equal to or higher than 0.5 atoms %, and preferably, equal to or higher than 3 atoms %, it is possible to absorb light in a more effective manner. In addition, it is possible to improve the bonding interface characteristics with the CBD buffer layer (described below).

The window layer 15 is a transparent conductive film having an n-type conductivity, a wide band gap, transparency, a low resistance, and a thickness of 0.05 to 2.5 μm. Representatively, the window layer 15 may include a zinc oxide-based thin film or an ITO thin film.

In the case of the zinc oxide-based thin film, the n-type window layer 15 is formed by using, as a dopant, anyone selected from a group-III element on a periodic table such as aluminum (Al), gallium (Ga), boron (B), or a combination thereof.

In the present embodiment, the high-resistance buffer layer 14 has a two-layer structure including a CBD buffer layer 141 as a first buffer layer and an MOCVD buffer layer 142 as a second buffer layer. However, the high-resistance buffer layer 14 may have a stack structure having three or more layers.

The CBD buffer layer 141 adjoins the top end face of the optical absorption layer 13 and is formed of a compound composed of cadmium (Cd), zinc (Zn), or indium (In).

The CBD buffer layer 141 has a thickness equal to or smaller than 20 nm, and preferably, equal to or smaller than 10 nm.

The CBD buffer layer 141 is manufactured using a chemical bath deposition (CBD) method. In the chemical bath deposition (CBD) method, a thin film is precipitated on a base material by immersing the base material in a solution containing a chemical species functioning as a precursor and promoting a heterogeneous reaction between the solution and the surface of the base material.

Specifically, ammonium hydroxide complex salt is formed, for example, by dissolving zinc acetate in ammonium hydroxide at a liquid temperature of 80° C. on the light absorbing layer 13, and a sulfur-containing zinc mixed crystal compound semiconductor thin film is chemically grown from the corresponding solution on the light absorbing layer 13 by dissolving sulfur-containing salt such as thiourea in that solution and making the resulting solution contact with light absorbing layer 13 for ten minutes. In addition, the grown sulfur-containing zinc mixed crystal compound semiconductor thin film is dried by annealing it at a setting temperature of 200° C. in the atmosphere for fifteen minutes. Furthermore, a high quality sulfur-containing zinc mixed crystal compound can be obtained by converting a part of zinc hydroxide within the film into zinc oxide and at the same time, promoting reformation of sulfur.

The CBD buffer layer 141 may contain CdₓS_{y}, ZnₓS_{y}, ZnₓO_{y}, Znₓ(OH)_{y}, InₓS_{y}, Inₓ(OH)_{y}, or InₓO_{y} (where, x and y denote any natural number) by adjusting the solution.

The MOCVD buffer layer 142 is formed of a zinc oxide-based thin film and adjoins the window layer 15.

In addition, a dopant contained in the MOCVD buffer layer 142 may include any one of aluminum (Al), gallium (Ga), boron (B), or the like. It is possible to obtain a high-resistance film appropriate as the buffer layer by adjusting the dopant concentration to be equal to or lower than 1×10¹⁹ atoms/cm³, and more preferably, equal to or lower than 1×10¹⁸ atoms/cm³.

The resistivity of the MOCVD buffer layer 142 is set to be equal to or higher than 0.1 Ωcm, and more preferably, equal to or higher than 1 Ωcm.

In the present embodiment, the MOCVD buffer layer 142 is formed using a metal organic chemical vapor deposition (MOCVD) method.

The MOCVD buffer layer 142 is formed, for example, by filling source materials including a metal organic compound material of zinc (Zn) (such as diethyl zinc or dimethyl zinc) and pure water in a bubbler or the like and bubbling the source materials using inert gas such as helium (He) or argon (Ar) so that a film is formed within a MOCVD apparatus in an accompanied manner.

Alternatively, the MOCVD buffer layer 142 may be formed using a sputtering method as well as the metal organic chemical vapor deposition (MOCVD) method. However, in order to obtain an excellent p-n junction interface with the light absorbing layer, the MOCVD method is more preferable than sputtering, in which high-energy particles act as a film formation species, because damage is seldom generated during film formation with the MOCVD method.

The MOCVD buffer layer 142 has a thickness equal to or larger than 100 nm.

Therefore, a ratio between the thickness of the CBD buffer layer 141 and the thickness of the MOCVD buffer layer 142 (the thickness of the MOCVD buffer layer 142/the thickness of the CBD buffer layer 141) is set to be equal to or larger than 5 (≧5).

In the related art, since the CBD buffer layer dominantly suppresses leakage, it is necessary to set the thickness of the CBD buffer layer to be equal to or larger than 50 nm. According to the present invention, since the MOCVD buffer layer 142 dominantly suppresses leakage, it is possible to set the thickness of the CBD buffer layer 141 to be equal to or smaller than 20 nm. As a result, it is possible to remarkably reduce the manufacturing time of the CBD buffer layer 141, realize high tact, reduce the manufacturing costs, and remarkably reduce the generation of waste during manufacturing the CBD buffer layer 141.

Furthermore, since the MOCVD buffer layer 142 has a dominant role in suppressing leakage, it is possible to increase the thickness of the MOCVD buffer layer, which is thin equal to or smaller than 50 nm in a typical case where the MOCVD buffer layer has a complementary role in suppressing leakage, to be equal to or larger than 100 nm. In addition, it is possible to adjust the concentration or resistivity of the dopant.

Characteristics of the solar cell according to the aforementioned embodiment are described below.

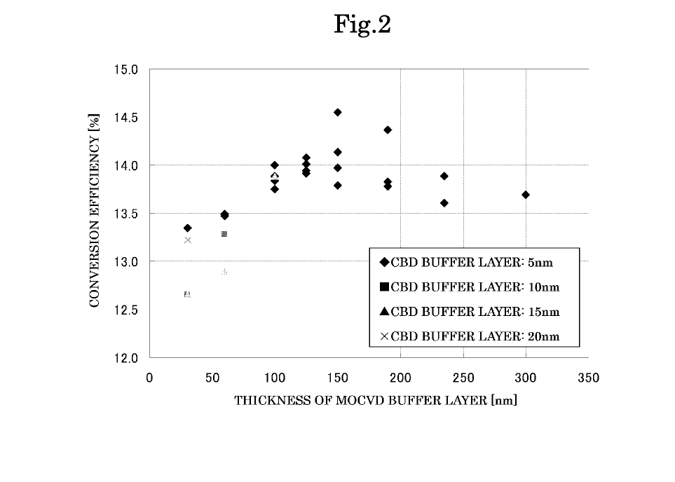

All of the results shown in FIGS. 2 to 5 are obtained by using an integrated structure having a substrate size of 30 cm×30 cm having the aforementioned stack structure. In this case, the resistivity of the MOCVD buffer layer 142 is set to 2 Ωcm.

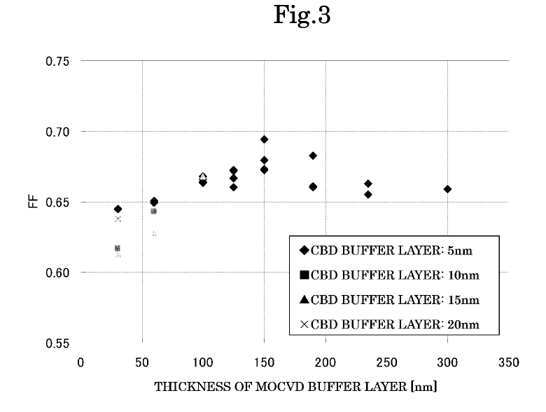

FIG. 2 is a characteristic graph regarding the thickness (nm) of the MOCVD buffer layer 142 and the conversion efficiency of the solar cell. FIG. 3 illustrates the relationship between the thickness (nm) of the MOCVD buffer layer 142 and a fill factor (FF) of the solar cell.

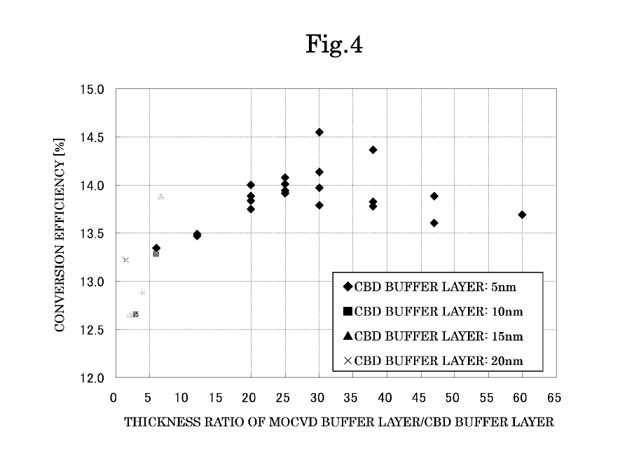

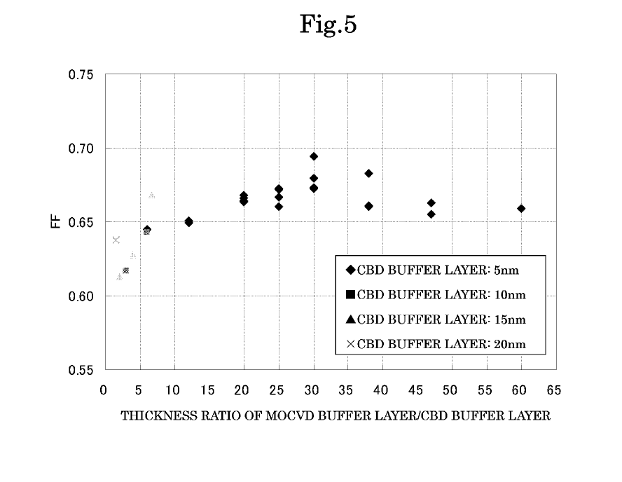

FIG. 4 illustrates the relationship between the thickness ratio of the MOCVD buffer layer 142/the CBD buffer layer 141 and the conversion efficiency (%). FIG. 5 illustrates the relationship between the thickness ratio between the MOCVD buffer layer 142/the CBD buffer layer 141 and the fill factor (FF).

In the graph of FIG. 2, the abscissa denotes the thickness of the MOCVD buffer layer 142, and the ordinate denotes the conversion efficiency (%). In the graph of FIG. 3, the abscissa denotes the thickness of the MOCVD buffer layer 142, and the ordinate denotes the fill factor (FF).

In the graph of FIG. 4, the abscissa denotes the thickness ratio of the MOCVD buffer layer 142/the CBD buffer layer 141, and the ordinate denotes the conversion efficiency (%). In the graph of FIG. 5, the abscissa denotes the thickness ratio of the MOCVD buffer layer 142/the CBD buffer layer 141, and the ordinate denotes the conversion efficiency (%).

In each of the graphs, the conversion efficiency depending on the thickness of the CBD buffer layer 141 and variation of the fill factor (FF) are presented.

As shown in FIGS. 2 and 3, it is possible to achieve an conversion efficiency equal to or higher than 13.5% using the CBD buffer layer having a thickness of 5 nm, 10 nm, 15 nm, or 20 nm by increasing the thickness of the MOCVD buffer layer 142 to be equal to or larger than 60 nm, and more preferably, equal to or larger than 100 nm.

In addition, in the relationship of the thickness ratio of (MOCVD buffer layer 142)/(CBD buffer layer 141), it is possible to achieve a conversion efficiency equal to or higher than 13.5% using the CBD buffer layer having a thickness of 5 nm, 10 nm, 15 nm, or 20 nm by setting the thickness ratio to be equal to or larger than 5, preferably equal to or larger than 10, and more preferably, equal to or larger than 20.

The fill factor (FF) is equal to or larger than 0.65 and has a larger value in the CIS based thin film solar cell having a large-sized integrated structure. This effect was achieved by reducing series resistance and suppressing leakage in the buffer layer structure of the present invention.

In this manner, in the stack structure according to the present embodiment, it is possible to obtain a stack structure of a high-efficiency solar cell by suppressing leakage without increasing series resistance and improving p-n heterojunction interface characteristics. Although, in the present embodiment, the resistivity of the MOCVD buffer layer 142 is set to 2 Ωcm, the same result can be obtained by setting the resistivity of the MOCVD buffer layer 142 to be equal to or higher than 0.1 Ωcm.

In addition, an example of the case where the aforementioned stack structure is applied to the stack structure of a CIS based thin film solar cell is described below.

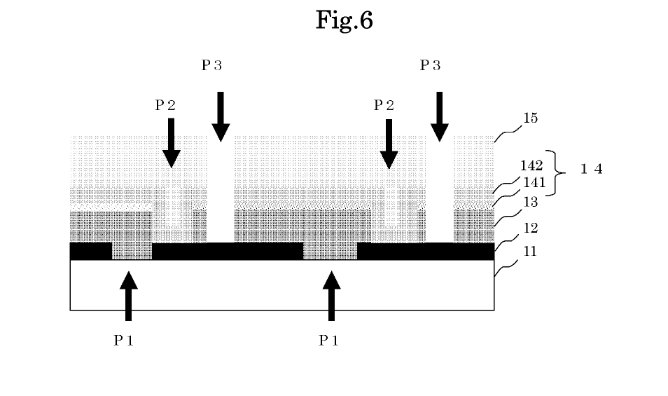

The stack structure of this case is shown in FIG. 6. In the example of FIG. 6, an electrode pattern P1 of the metal back electrode layer 12 is formed on the substrate 11, and an interconnect pattern P2 is formed using a mechanical scribe apparatus or a laser scribe apparatus at the time point that the light absorbing layer 13 and the CBD buffer layer 141 are formed thereon. Subsequently, the MOCVD buffer layer 142 is manufactured thereon using a metal organic chemical vapor deposition (MOCVD) method.

After the window layer 15 is manufactured, an interconnect pattern P3 is formed using a mechanical scribe apparatus or a laser scribe apparatus so that the stack structure of the solar cell is configured.

Since the MOCVD buffer layer 142 is manufactured after the interconnect pattern P2 is formed, the side end face of the CBD buffer layer 141 and the light absorbing layer 13 exposed by the interconnect pattern P2 as well as the surface of the CBD buffer layer 141 are covered. As a result, it is also possible to suppress leakage in the end face and obtain a passivation effect in the end face.

In addition, although it is difficult to manufacture the MOCVD buffer layer 142 in the end face of the interconnect pattern, it is possible to manufacture a film with an excellent coverage using the metal organic chemical vapor deposition (MOCVD) method.

### BRIEF DESCRIPTION OF DRAWINGS

[FIG. 1] FIG. 1 illustrates a stack structure of the CIS solar cell according to an embodiment of the present invention.

[FIG. 2] FIG. 2 is a graph illustrating a relationship between the thickness of the MOCVD buffer layer and the conversion efficiency.

[FIG. 3] FIG. 3 is a graph illustrating a relationship between the thickness of the MOCVD buffer layer and the fill factor (FF).

[FIG. 4] FIG. 4 is a graph illustrating a relationship between the thickness ratio of the MOCVD buffer layer/the CBD buffer layer and the conversion efficiency.

[FIG. 5] FIG. 5 is a graph illustrating a relationship between the thickness ratio of the MOCVD buffer layer/the CBD buffer layer and the fill factor (FF).

[FIG. 6] FIG. 6 illustrates an example of an integrated structure of a CIS solar cell using a stack structure according to an embodiment of the present invention.

### EXPLANATION OF REFERENCE

11 GLASS SUBSTRATE
12 METAL BACK ELECTRODE LAYER
13 LIGHT ABSORBING LAYER
14 HIGH-RESISTANCE BUFFER LAYER
15 WINDOW LAYER
141 CBD BUFFER LAYER (FIRST BUFFER LAYER)
142 MOCVD BUFFER LAYER (SECOND BUFFER LAYER)
P1 PATTERN 1
P2 PATTERN 2
P3 PATTERN 3

1. A stack structure of a CIS based thin film solar cell obtained by stacking a p-type CIS light absorbing layer, a buffer layer, and an n-type transparent conductive film in that order,
wherein the buffer layer has a stack structure of two or more layers including first and second buffer layers,
the first buffer layer adjoining the p-type CIS light absorbing layer is made of a compound containing cadmium (Cd), zinc (Zn), or indium (In),
the second buffer layer adjoining the first buffer layer is made of a zinc oxide-based thin film,
the first buffer layer has a thickness equal to or smaller than 20 nm, and
the second buffer layer has a thickness equal to or larger than 100 nm.

2. A stack structure of a CIS based thin film solar cell obtained by stacking a p-type CIS light absorbing layer, a buffer layer, and an n-type transparent conductive film in that order,
wherein the buffer layer has a stack structure of two or more layers including first and second buffer layers,
the first buffer layer adjoining the p-type CIS light absorbing layer is made of a compound containing cadmium (Cd), zinc (Zn), or indium (In),
the second buffer layer adjoining the first buffer layer is made of a zinc oxide-based thin film, and
a ratio between a thickness of the first buffer layer and a thickness of the second buffer layer (the thickness of the second buffer layer/the thickness of the first buffer layer) is set to be equal to or larger than 5.

3. The stack structure of the CIS based thin film solar cell according to claim 1, wherein the first buffer layer is formed using a chemical bath deposition (CBD) method.

4. The stack structure of the CIS based thin film solar cell according to claim 1, wherein the second buffer layer is formed using a metal organic chemical vapor deposition (MOCVD) method.

5. The stack structure of the CIS based thin film solar cell according to claim 1, wherein a concentration of a dopant contained in the second buffer layer is equal to or lower than 1×10¹⁹ atoms/cm³.

6. The stack structure of the CIS based thin film solar cell according to claim 5, wherein the dopant contains any one of aluminum (Al), gallium (Ga), or boron (B).

7. The stack structure of the CIS based thin film solar cell according to claim 1, wherein the first buffer layer contains any one of CdₓS_{y}, ZnₓS_{y}, ZnₓO_{y}, Znₓ(OH)_{y}, InₓS_{y}, Inₓ(OH)_{y}, or InₓO_{y} (where, x and y denote any natural number).

8. The stack structure of the CIS based thin film solar cell according to claim 1, wherein a concentration of sulfur (S) on a surface of the p-type CIS light absorbing layer is equal to or higher than 0.5 atoms %.

9. The stack structure of the CIS based thin film solar cell according to claim 1, wherein the second buffer layer has resistivity equal to or higher than 0.1 Ωcm.

10. An integrated structure of a CIS based thin film solar cell including the stack structure according to claim 1.

11. The stack structure of the CIS based thin film solar cell according to claim 2, wherein the first buffer layer is formed using a chemical bath deposition (CBD) method.

12. The stack structure of the CIS based thin film solar cell according to claim 2, wherein the second buffer layer is formed using a metal organic chemical vapor deposition (MOCVD) method.

13. The stack structure of the CIS based thin film solar cell according to claim 2, wherein a concentration of a dopant contained in the second buffer layer is equal to or lower than 1×10¹⁹ atoms/cm³.

14. The stack structure of the CIS based thin film solar cell according to claim 13, wherein the dopant contains any one of aluminum (Al), gallium (Ga), or boron (B).

15. The stack structure of the CIS based thin film solar cell according to claim 2, wherein the first buffer layer contains any one of CdₓS_{y}, ZnₓS_{y}, ZnₓO_{y}, Znₓ(OH)_{y}, InₓS_{y}, Inₓ(OH)_{y}, or InₓO_{y} (where, x and y denote any natural number).

16. The stack structure of the CIS based thin film solar cell according to claim 2, wherein a concentration of sulfur (S) on a surface of the p-type CIS light absorbing layer is equal to or higher than 0.5 atoms %.

17. The stack structure of the CIS based thin film solar cell according to claim 2, wherein the second buffer layer has resistivity equal to or higher than 0.1 Ωcm.

18. An integrated structure of a CIS based thin film solar cell including the stack structure according to claim 2.
